(19) United States
(12) Patent Application Publication
(10) Pub. No.: US 2011/0305231 A1
(43) Pub. Date: Dec. 15, 2011

(54) Communication System for Short Range Reliable Information Transfer

(76) Inventors: Martin Tomlinson, Devon (GB); Cen Jung Tjhai, Plymouth (GB)

(21) Appl. No.: 13/054,052

(22) PCT Filed: Jul. 17, 2010
(86) PCT No.: PCT/GB2009/001769

§ 371 Date: Apr. 6, 2011

(30) Foreign Application Priority Data
Jul. 17, 2008 (GB) 0813074.2
Feb. 12, 2009 (GB) 0302293.0

(51) Int. Cl. H04W 84/02; H03M 13/00; H04B 7/00; H04J 1/00; H04J 3/00

(52) U.S. Cl. 370/338; 370/343; 370/345; 714/746

(57) ABSTRACT

The invention is concerned with providing a wireless transmitting and receiving system such that an information stream may be exchanged in both directions over a relatively short range and with a high level of robustness and tolerance to propagation conditions. Several applications are envisaged, such as a hand-off internet radio system in which the user equipment may resemble a traditional domestic analogue radio set combining features of robustness and high audio quality but able to play audio streams from internet radio stations, talking books and encoded music together with a transmitting command system. Other envisaged applications include robust tracking and location systems, range extension of wireless systems such as WiFi, Bluetooth and a robust video streaming system. The unlicensed low power Instrument Scientific Medical (ISM) and Short Range Devices (SRD) frequency bands are well suited to be used by the invention. The invention matches the baseband bandwidth and number of baseband channels to the propagation conditions of the wireless link, provides low peak to average spectral power density and automatic error correction without synchronisation dependency. These features make the invention extremely tolerant to the high variability in propagation conditions which are commonly experienced in indoor wireless reception. wireless hand-off transmitting and receiving system such that a radio station streamed over the internet may be received wirelessly using a receiver which to the user may resemble a traditional domestic analogue radio set combining features of robustness and high audio quality. A return communication channel provides an automatic means of adapting to changing propagation conditions of the wireless link as well as providing the user with the ability to control the information being received.

### FIELD OF THE INVENTION

The present invention relates to a robust wireless communication system which enables information to be transmitted and received reliably using a wireless transceiver up to 1 km from the source of information which may be a generic information source, an internet access point, a hard drive, a command signal transducer, or a code carrying position information. Examples of specific applications for the invention include a hand-off internet radio system, short range video streaming, position finding and tracking, WiFi/Bluetooth range extension and general alarm communications.

### BACKGROUND OF THE INVENTION

It is a fundamental law of information theory that:

$$C \leq W {log}_{2} ( \frac{S + N}{N} )$$

and the information rate, C, able to be communicated by the communication system, is proportional to the bandwidth, W, and the logarithm of the ratio of the received signal power, S plus noise power, N, to the noise power, N. For a given communication technology, the ratio of the received signal power, S plus noise power, N, to the noise power, is a fixed ratio constant R_{tec}. Accordingly:

$$\frac{S}{N} = {R}_{tec} - 1$$

$$and$$

$$C \leq W {log}_{2} {R}_{tec}$$

with noise spectral density defined as No, N=WNo and

$$W \geq \frac{C}{{log}_{2} {R}_{tec}}$$

and after substitution it is found that

$$S \geq \frac{C \cdot {N}_{o} ( {R}_{tec} - 1 )}{{log}_{2} {R}_{tec}}$$

The term

$$\frac{{N}_{o} ( {R}_{tec} - 1 )}{{log}_{2} {R}_{tec}}$$

is a constant for a given communications technology and may be conveniently represented as the constant M_{tec}. The final result is the relationship between the received power and the information rate able to be communicated, namely:

S≧C·M_{tec}

This indicates that the required, received signal power is directly proportional to the information rate carried by the communication system. Since received signal power is proportional to transmitted power it is apparent that the required transmitter power is directly proportional to the information rate carried by the communication system. For example a communication system conveying a multiplex of 16 stereo radio channels will require 16 times the transmitter power of a communication system conveying a single stereo radio channel. A Wi-Fi link with capacity of 54 Mbits/sec will require 54 times the transmitter power of a digital communications link with capacity 1 Mbit/sec. If the same transmitter power is used, the lower capacity system will have the greater range. This range is a function of the particular monotonic function which describes the average Radio Frequency (RF) propagation loss given a choice of carrier frequency and the surrounding environment such as any buildings, trees and foliage. The extent of which determine the slope of the monotonic function.

It is an aim of the present invention to provide a communications system that makes more efficient use of the available radio frequency spectrum, thereby increasing the range of transmission in certain applications.

### SUMMARY OF THE INVENTION

In a first aspect of the present invention, there is provided an information transfer system comprising:
a transmitter; and
a receiver,
wherein data received and/or stored locally by the transmitter is selected by a user using a remote control channel and decoded by the transmitter into baseband components which are filtered according to user preferences communicated to the transmitter by the remote control channel, and each of these baseband components are encoded by the transmitter using an error correcting code into an information sample stream and a second stream consisting of sequences of parity symbols plus synchronisation sequences, and each stream is frequency division multiplexed by the transmitter into a single signal which is scrambled by the transmitter so as to produce a signal power spectral density which has a low peak to average ratio and the scrambled signal stream is digitally modulated by the transmitter onto a carrier which in turn is radiated by an antenna as a wireless signal,
wherein the wireless signal is received by the receiver using a second antenna and demodulated into a single signal stream which is descrambled and then demultiplexed into baseband information streams together with associated parity symbols and synchronisation sequences and in which the synchronisation information is used to decode each received codeword generating a sequence of information symbols which are substituted for information samples received in error and the resulting information streams are filtered according to user preferences and output.

The system can be advantageously used in any data transfer system, for example in a hand-off interne radio system. For a hand-off interne radio application, the system is such that the wireless transceiver may resemble from the user's viewpoint a conventional, portable broadcast radio with instant access to stations, without the features of long drop outs due to synchronisation loss, sudden loss of signal and other negative aspects associated with digital radio. The invention may be used at any wireless frequency but will find most applications in the unlicenced Instrument Scientific Model (ISM) and Short Range Devices (SRD) frequency bands. Short range, low power wireless links, particularly when received within a building feature high attenuation, shadowing, and multipath propagation with wide variations in signal strength, which is sometimes time varying. The system of the present invention is tolerant to these propagation characteristics, providing a quasi error free output free from synchronisation glitches and making efficient use of the available received power.

In a second aspect of the present invention, there is provided a system for extending a communication range of a wireless data communications link, comprising:
a transmitter; and
a receiver,
wherein the transmitter is adapted to encode a bit stream in each direction over the link using an error correcting code to produce an information bit stream and a second bit stream consisting of sequences of parity bits plus synchronisation sequences,
wherein the transmitter is further adapted to frequency division multiplex each stream into a single signal and scramble it so as to produce a signal power spectral density which has a low peak to average ratio,
wherein the scrambled signal stream is modulated onto a carrier which in turn is radiated by an antenna as a wireless signal; and
wherein the receiver is adapted to receive the wireless signal via a second antenna and demodulate it into a single signal stream which is descrambled and then demultiplexed into a baseband information bit stream together with an associated baseband parity bit stream and synchronisation sequences,
wherein the receiver is further adapted to use the synchronisation information to decode each received codeword thereby generating a sequence of information bits which are substituted for information bits received in error.

Short range, low power wireless links, particularly when received within a building feature high attenuation, shadowing, and multipath propagation with wide variations in signal strength, which is sometimes time varying. The system of the present invention is tolerant to these propagation characteristics, providing a quasi error free output free from synchronisation glitches and making efficient use of the available received power.

In a third aspect of the present invention, there is provided a system for extending a communication range of a first wireless data communications link using a second wireless data communications link, comprising:
a transmitter; and
a receiver,
wherein the transmitter is adapted to receive and to decode the data being sent over the first wireless link and to encode the resulting bit stream in each direction of transmission over the link using an error correcting code to produce an information bit stream and a second bit stream consisting of sequences of parity bits plus synchronisation sequences,
wherein the transmitter is further adapted to frequency division multiplex each stream into a single signal and scramble it so as to produce a signal power spectral density which has a low peak to average ratio,
wherein the scrambled signal stream is modulated onto a carrier which in turn is radiated by an antenna as a wireless signal; and
wherein the receiver is adapted to receive the wireless signal via a second antenna and demodulate it into a single signal stream which is descrambled and then demultiplexed into a baseband information bit stream together with an associated baseband parity bit stream and synchronisation sequences,
wherein the receiver is further adapted to use the synchronisation information to decode each received codeword thereby generating a sequence of information bits which are substituted for information bits received in error and these bits are encoded and modulated onto a wireless carrier compatible with the receiver of the first wireless link.

Short range, low power wireless links, particularly when received within a building feature high attenuation, shadowing, and multipath propagation with wide variations in signal strength, which is sometimes time varying. The features of the present invention provide a tolerance to these propagation characteristics, providing a quasi error free output free from synchronisation glitches, extending the useful range of the communication system and making efficient use of the available received power.

In a fourth aspect of the present invention, there is provided a system in which information to be transmitted is selected by the user using a remote control channel and decoded into baseband components which are filtered according to user preferences communicated by the remote control channel and time division multiplexed into a single signal stream which is digitally compressed to reduce the information content, and the compressed output is encoded using an error correcting code which is modulated onto a carrier which in turn is radiated by an antenna as a wireless signal, and the wireless signal is received using a second antenna and demodulated into a single signal stream which is decoded using the error correcting code, and the decoded output is digitally decompressed forming an output which is demultiplexed into baseband components each of which is filtered according to user preferences and presented at the output.

Short range, low power wireless links, particularly when received within a building feature high attenuation, shadowing, and multipath propagation with wide variations in signal strength, which is sometimes time varying. The features of the present invention provide a tolerance to these propagation characteristics, providing a quasi error free output free from synchronisation glitches, extending the useful range of the communication system and making efficient use of the available received power.

By stipulating “a signal power spectral density which has a low peak to average ratio”, an example of such a signal power spectral density is one in which the signal measured in any 100 Hz bandwidth within the passband over any 1 second period does not exceed the average power density level by more than 25% with a probabilty greater than 0.99. Another example of a suitable signal power spectral density is one which is identical, substantially the same as, or similar to the spectral density of Gaussian distributed noise.

In a fifth aspect of the present invention, there is provided a system in which information to be transmitted is selected by the user using a remote control channel and decoded into baseband components which are filtered according to user preferences communicated by the remote control channel, and these baseband components are time division multiplexed into a single signal stream which is scrambled so as to produce a signal power spectral density which has a low peak to average ratio and the scrambled signal stream is analogue modulated onto a carrier which in turn is radiated by an antenna as a wireless signal, and the wireless signal is received using a second antenna and demodulated into a single signal stream which is descrambled and then demultiplexed into baseband components each of which is filtered according to user preferences and presented at the output.

Short range, low power wireless links, particularly when received within a building feature high attenuation, shadowing, and multipath propagation with wide variations in signal strength, which is sometimes time varying. The features of the present invention provide a tolerance to these propagation characteristics, providing a quasi error free output free from synchronisation glitches, extending the useful range of the communication system and making efficient use of the available received power.

Some or all of the baseband components in the transmitter may be weighted and added together so as to reduce the number of baseband components which in turn reduces the information bit rate conveyed by the wireless carrier. Some or all of the baseband components in the transmitter may be weighted and added together so as to reduce the bandwidth of the signal conveyed by the wireless carrier.

Preferably, the information to be transmitted is audio and/or video data streamed over the internet, such as a radio channel.

Advantageously, the return channel may be used automatically and adaptively to select parameter options so as to increase or to decrease the robustness of the wireless link to match the wireless propagation conditions.

A transmitter may be adapted to receive and/or store locally data, which is selected by a user using a remote control channel and decoded by the transmitter into baseband components which are filtered according to user preferences communicated to the transmitter by the remote control channel, and each of these baseband components are encoded by the transmitter using an error correcting code into an information sample stream and a second stream consisting of sequences of parity symbols plus synchronisation sequences, and each stream is frequency division multiplexed by the transmitter into a single signal which is scrambled by the transmitter so as to produce a signal power spectral density which has a low peak to average ratio and the scrambled signal stream is digitally modulated by the transmitter onto a carrier which in turn is radiated by an antenna as a wireless signal.

A receiver may be adapted to receive the wireless signal generated by the above transmitter using a second antenna and to demodulate it into a single signal stream which is descrambled and then demultiplexed into baseband information streams together with associated parity symbols and synchronisation sequences and in which the synchronisation information is used to decode each received codeword generating a sequence of information symbols which are substituted for information samples received in error and the resulting information streams are filtered according to user preferences and output.

In the aforementioned systems, transmitters and receivers, both frequency and time division multiplexing of information and parity bit streams may be used together in combination, resulting in a hybrid multiplexed arrangement. Hence, multiplexing by both frequency and time division may occur successively, or at the same time, in the transmitter. Subsequently, demultiplexing from the frequency and time division domains would occur in the receiver.

### BRIEF DESCRIPTION OF THE DRAWINGS

The present invention is described by way of reference to the accompanying drawings, in which:

FIG. 1 is a block diagram of one embodiment of the invention in a hand-off transmitter arrangement using digital modulation.

FIG. 2 is a block diagram of the hand-off receiver arrangement using digital modulation according to the embodiment of FIG. 1.

FIG. 3 is a block diagram of an alternative embodiment of the invention in a hand-off transmitter arrangement using analogue modulation.

FIG. 4 is a block diagram of the hand-off receiver arrangement using analogue modulation according to the embodiment of FIG. 3.

FIG. 5 shows the baseband spectrum for combined signal for FDM stereo.

FIG. 6 is a block diagram of the hand-off transmitter arrangement for monophonic signal.

FIG. 7 is a block diagram of the hand-off receiver arrangement for monophonic signal.

FIG. 8 shows a typical PAM signal sequence for stereo baseband pair of signals.

FIG. 9 is a block diagram of the encoder, multiplexer and modulator arrangement at hand-off transmitter for PAM stereo information sample streams.

FIG. 10 is a block diagram of the demodulation, demultiplexing, and PAM stereo sample streams error correction arrangement at the hand-off receiver.

FIG. 11 is a block diagram of the encoder, multiplexer and modulator arrangement for WiFi range extension according to on embodiment of the invention.

FIG. 12 is a block diagram of the demodulation, demultiplexing, and error correction arrangement of WiFi bit stream.

FIG. 13 is a block diagram of the encoder, multiplexer and modulator arrangement for adding robustness to location and tracking bit stream.

FIG. 14 is a block diagram of the demodulation, demultiplexing, and error correction arrangement to add robustness to location and tracking bit stream according to one embodiment of the invention.

FIG. 15 is a block diagram of the encoder, multiplexer and modulator arrangement for adding robustness to video bit stream according to one embodiment of the invention.

FIG. 16 is a block diagram of the demodulation, demultiplexing, and error correction arrangement to add robustness to video bit stream according to one embodiment of the invention.

FIG. 17 is a block diagram of the demodulation, and error correction arrangement to add robustness to an existing wireless system according to one embodiment of the invention.

FIG. 18 is a block diagram of the modulation, and error correction arrangement to add robustness to an existing wireless system according to one embodiment of the invention.

### DETAILED DESCRIPTION OF THE DRAWINGS

The invention is described below in the following description in terms of the internet radio hand-off system application by way of example only. The invention may be implemented in other environments and used in other applications, some examples of which are also described below.

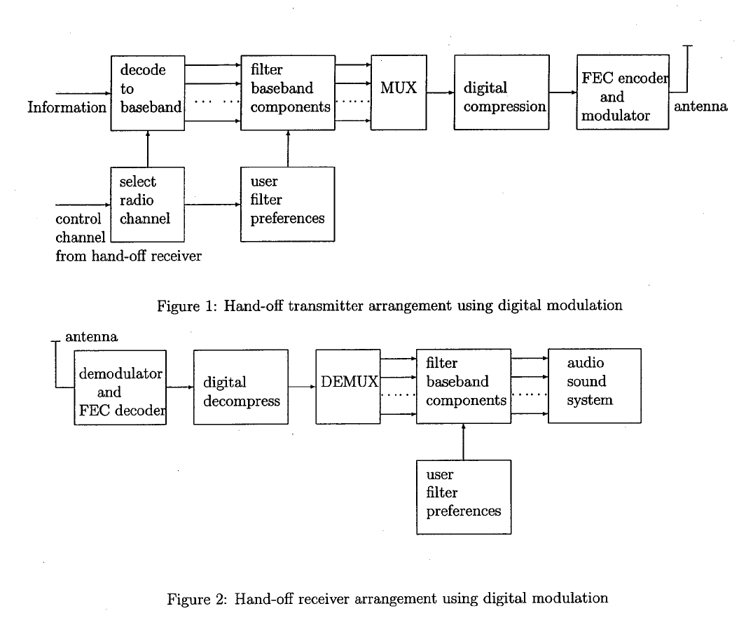

The system of the wireless hand-off transmitter arrangement of the invention is shown in FIG. 1. The required internet radio station is selected using a control channel from the wireless hand-off receiver and the corresponding baseband signals are extracted from the bit stream or multiplex stream conveying the selected radio channel. (The control channel may be provided by one of several conventional remote control means.) The baseband signals may consist of a monophonic, stereophonic, or a greater number of baseband signals. Depending on the audio quality required by the user, and selected by the user as shown in FIG. 1 these baseband signals are bandlimited and subjected to information reductions so as to reduce the information rate that the hand-off wireless link has to support. The filtered baseband components are multiplexed together using the well known techniques[1] of Frequency Division Multiplexing (FDM) or Time Division Multiplexing (TDM) in the MUX shown in FIG. 1 and digitally compressed using one of the several known methods in the public domain [2]. The compressed signal is Forward Error Correction (FEC) encoded [3] to enable the wireless hand-off receiver to correct errors incurred in transmission. The resulting encoded signal is modulated onto a suitable carrier frequency, amplified and radiated from the antenna as shown in FIG. 1.

The outline system of the wireless hand-off receiver arrangement of the invention is shown in FIG. 2. The radiated signal from the transmitter is converted to an electrical signal by the antenna, demodulated and any transmission errors are corrected by the FEC decoder. The decoded signal is decompressed and demultiplexed to produce baseband signals as shown in FIG. 2. These baseband signals are reconstructions of the baseband signals that were present in the hand-off transmitter. The reconstructed baseband signals are amplified, filtered according to user preference, and output to the audio sound system which converts the reconstructed baseband signals to audio using a loudspeaker arrangement or headphones in the conventional manner as shown in FIG. 2.

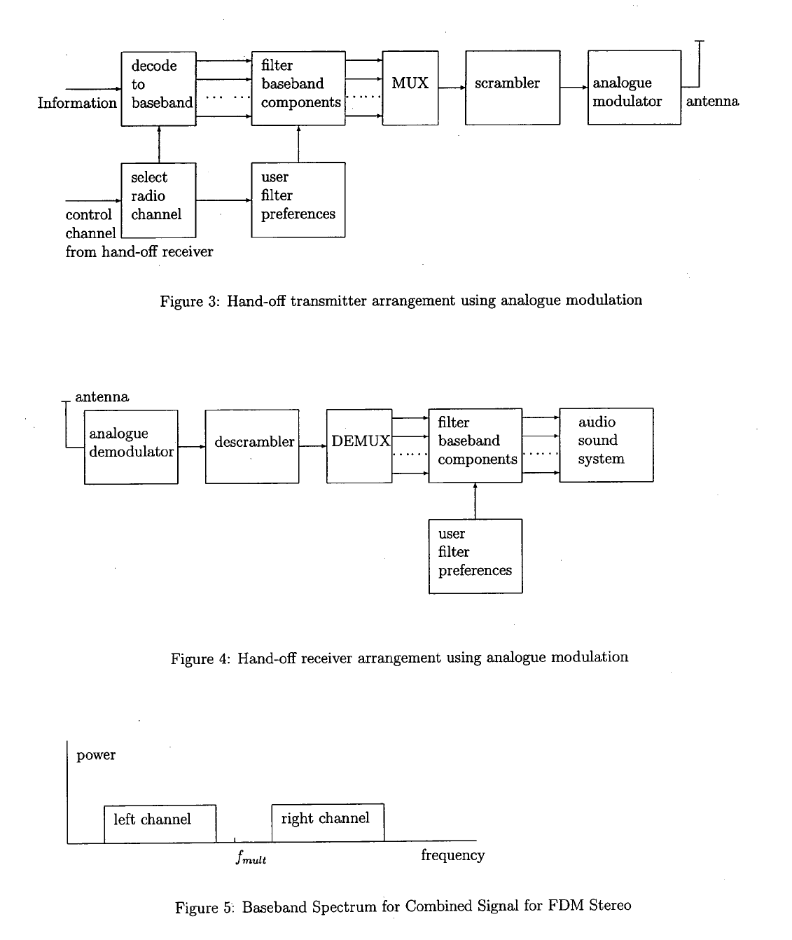

In another embodiment of the invention, analogue modulation using Frequency Modulation (FM), Phase Modulation (PM) or Amplitude Modulation (AM) maybe used [4] instead of digital modulation for the wireless link. The arrangement for the hand-off transmitter is shown in FIG. 3. The required interne radio station is selected by the user using a control signal emanating from the wireless hand-off receiver and the corresponding baseband signals are decoded from the bit stream or multiplex stream conveying the selected radio channel. The baseband signals may consist of a monophonic, stereophonic, or a greater number of baseband signals. Depending on the audio quality required by the user, and selected by the user as shown in FIG. 3 these baseband signals are bandlimited so as to reduce the total baseband signal bandwidth that the hand-off wireless link has to support. The filtered baseband components are multiplexed together using TDM or FDM to produce a combined signal which is input to the scrambler prior to the analogue modulator which modulates the scrambled, combined signal onto a suitable carrier frequency. The scrambler may be one of the many scrambler types known, for example see [5,6]. The purpose of the scrambler is not to provide security or rights management, it is to produce a uniform power spectral density of the combined signal which in turn causes the modulated signal to have a uniform power spectral density. As a result, greater power is permitted to be emitted from the antenna by the radio licensing authorities, in some cases, increasing the robustness or range of the wireless link. The modulated signal is amplified and radiated from the antenna as shown in FIG. 3.

At the wireless hand-off receiver the radiated signal from the transmitter is converted into an electrical signal by the antenna, and demodulated to produce a similar version to the scrambled, combined signal which was present in the transmitter. The scrambled, combined signal is descrambled by the descrambler and the result is demultiplexed in the DEMUX to produce similar versions of the baseband signals present in the transmitter. The baseband signals obtained from demultiplexing are amplified, filtered according to user preference, and output to the audio sound system which converts the reconstructed baseband signals to audio using a loudspeaker arrangement or headphones in the conventional manner as shown in FIG. 4.

One example of the spectrum resulting from one possible multiplexing of the baseband signals is shown in FIG. 5 for the case where FDM is used for a stereo system in which case there are two baseband signals prior to multiplexing. The spectrum shown in FIG. 5 is the result of adding the left channel to the single sideband modulated right channel where fₘᵤₗₜ is the sub-carrier frequency. (As is the convention, the term sub-carrier is used to denote the carrier frequency of the FDM in order to avoid confusion with the main carrier frequency of the analogue modulator shown in FIG. 3.)

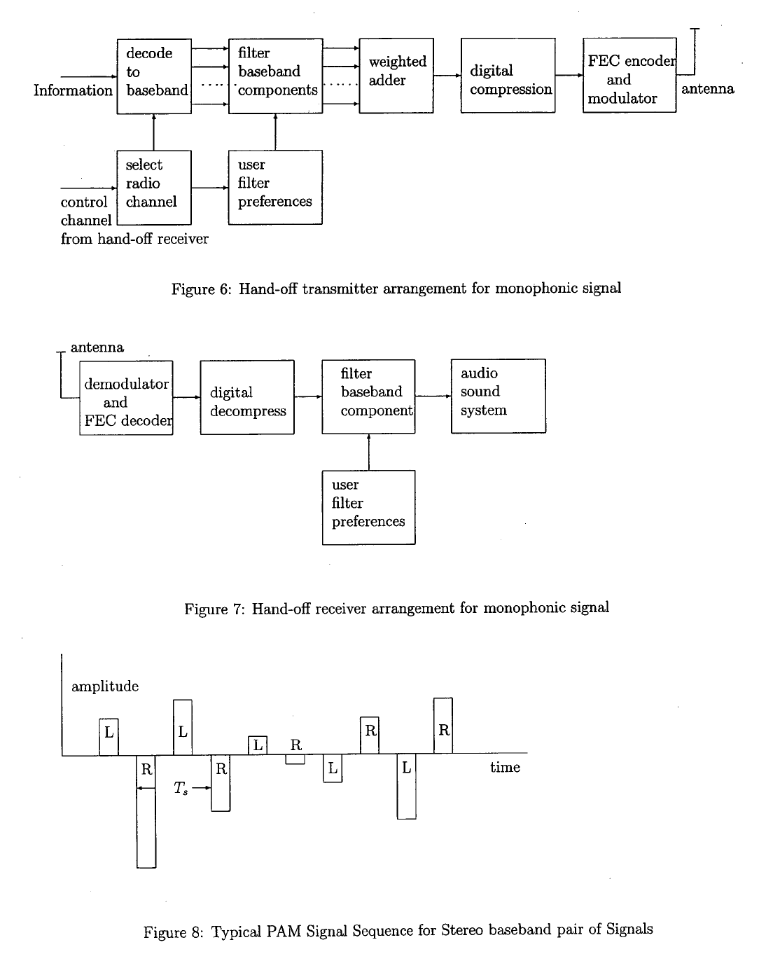

In a further embodiment of the invention some or all of the baseband signals may be weighted and added together in order to reduce the information rate that has to be supported by the wireless link. The simplest case is where there is only one, monophonic, baseband component and it may be noted that the majority of conventional radio receivers are monophonic. An example of this embodiment of the invention is shown for the wireless hand-off transmitter arrangement using digital modulation in FIG. 6 for a monophonic system. The required internet radio station is selected using a control channel from the wireless hand-off receiver and the corresponding baseband signals are extracted from the bit stream or multiplex stream conveying the selected radio channel. It is obvious that system may be extended to include baseband signals that are stereophonic, or have a greater number of baseband signals. Depending on the audio quality required by the user, and selected by the user as shown in FIG. 6 these baseband signals are bandlimited, multiplied by fixed coefficients, that is weighted, according to user preference and added together to form a monophonic signal as shown in FIG. 6. This signal is digitally compressed to form a compressed signal which is Forward Error Correction (FEC) encoded to enable the wireless hand-off receiver to correct any errors incurred in transmission. The resulting encoded signal is modulated onto a suitable carrier frequency, amplified and radiated from the antenna as shown in FIG. 6.

The outline system of the wireless hand-off receiver arrangement for this embodiment of the invention is shown in FIG. 7. The radiated signal from the transmitter is converted to an electrical signal by the antenna, demodulated and any transmission errors are corrected by the FEC decoder. As shown in FIG. 7 the decoded signal is then decompressed to produce a monophonic baseband signal. This baseband signal is a reconstruction of the monophonic baseband signal that was present in the monophonic hand-off transmitter. The reconstructed baseband signal is amplified, filtered according to user preference, and output to the audio sound system which converts the reconstructed monophonic baseband signal to audio using a loudspeaker arrangement or headphones in the conventional manner as shown in FIG. 7.

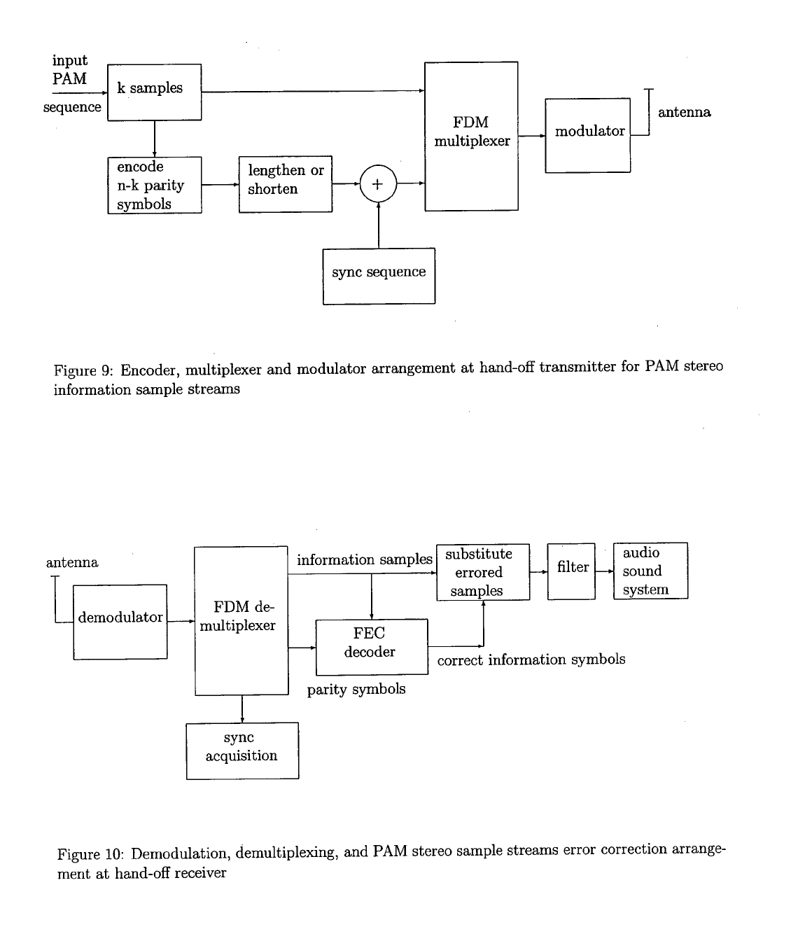

In another embodiment of the invention the baseband signals that are extracted from the bit stream or multiplex conveying the selected radio station are initially filtered and sampled to produce a PAM signal sequence, multiplexed in the time domain. In the following, by way of example a stereo pair of baseband signals are considered with a sample rate of fₛ and a period between samples of Tₛ with each PAM sample of the right channel preceded by a PAM sample of the left channel. A typical sequence of these PAM signals is shown in FIG. 8 with each sample of the right channel, designated as R in FIG. 8 and each sample of the left channel, designated as L in FIG. 8. These PAM samples are designated as information symbols and are encoded as shown in FIG. 9. A separate synchronisation signal is transmitted which enables the hand-off receiver to differentiate between left and right channel PAM samples and also indicates the beginning of each block of k information symbols. The PAM samples that are reconstituted in the hand-off receiver will be subject to errors as a result of the wireless transmission and these errors are corrected in the hand-off receiver as shown in FIG. 10. In the encoder at the hand-off transmitter as shown in FIG. 9, each sequence of k PAM samples, k/2 PAM samples from the left channel and k/2 PAM samples from the right channel are encoded into n-k parity symbols to form a codeword from an error correcting code of total length n symbols consisting of a total sequence of n symbols made up of k PAM samples and n-k parity symbols. As shown in FIG. 9 a synchronisation sequence is appended to every sequence of the n-k parity symbols. The n-k parity symbols are lengthened or shortened in time so that the total duration of the n-k parity symbols plus the synchronisation sequence is equal to the duration of the k information symbols. This is so that in the hand-off receiver the information symbols may be output without interruption even if synchronisation is temporarily lost or if the error correction decoder is overloaded due to adverse propagation conditions. As shown in FIG. 9, the n-k parity symbols plus the synchronisation sequence is frequency division multiplexed together with the k information PAM samples, and the resulting signal modulated and transmitted. There are a number of known different ways that the PAM samples may be formatted [1] prior to frequency division multiplexing. The PAM signals may be quantised into Pulse Code Modulation (PCM) symbols and the bits which constitute each symbol, streamed in sequence. Alternatively bits may be grouped together to form multi-level symbols. One example is quarternary symbols. A further option is to retain the original PAM format for the PAM information samples, and to frequency multiplex the PAM information sample stream and the parity symbol stream including synchronation sequences. A common failure of nearly all wireless, digital communication systems is that they suffer from catastrophic failure when propagation conditions exceed prescribed limits and as a result significant outages are produced. This is avoided in the invention by communicating the n-k parity symbols to the receiver independently of the k information PAM samples by frequency multiplexing each stream prior to modulation. The error correcting code that is used may be a multi-level Bose Chaudhuri Hocqenheim (BCH) code [3] if quantisation of the PAM information samples is carried out prior to encoding. Alternatively if no quantisation is carried out, a complex number field error correcting code maybe used directly to encode the PAM information samples [7]. As shown in FIG. 9 after frequency multiplexing the resulting signal is modulated and radiated by the antenna. The hand-off receiver arrangement for this embodiment of the invention is shown in FIG. 10. The received signal from the antenna is demodulated and the information PAM samples are demultiplexed into a separate stream from the synchronisation sequences and parity PAM symbol stream. The idea is that the information PAM samples have a direct output path to the audio sound system so that under adverse propagation conditions where synchronisation may be lost, or the error correction system may be overloaded, the information PAM samples, albeit with errors, continue to be output thereby producing a robust system. As shown in FIG. 10, with each sequence of k PAM information samples and n-k parity symbols, the synchronisation sequence is acquired which provides synchronisation information regarding the beginning of each codeword and the relative phasing of the PAM information samples for the left hand and right hand stereo channels. Each codeword is decoded and a codeword is found from the (n,k) error correcting code which is the closest to the received information samples and parity symbols in terms of Euclidean distance [3]. The information samples from the PAM information samples stream that differ from the codeword information symbols are in error. The correct information symbols are substituted for the incorrect information PAM samples as shown in FIG. 10.

In the event that propagation conditions are so poor that error correction becomes unreliable the procedure of substituting errored information PAM samples with information symbols from the error correcting decoder may be suspended. Poor propagation conditions may detected by observing a reduced margin in synchronisation detection. It is clear that the invention may be used as a robust delivery system to convey other audio information streams to the user to include talking books and digitally compressed music such as MP3 encoded music files.

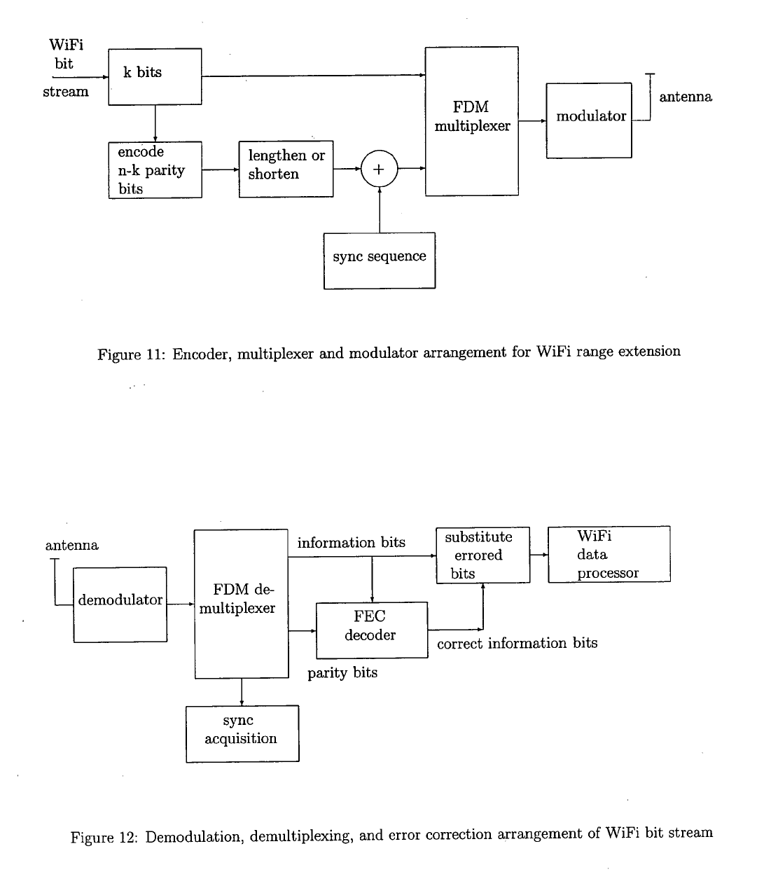

For the application of WiFi range extension in this embodiment of the invention, the transmitter arrangement is shown in FIG. 11. After conventional demodulation and decoding the WiFi bit stream is input k bits at a time as shown in FIG. 11. Each sequence of k bits is encoded into n-k parity bits to form a codeword from an error correcting code of total length n bits consisting of a total sequence of n bits made up of k information bits and n-k parity bits. As shown in FIG. 11 a synchronisation sequence is appended to every sequence of the n-k parity bits. The n-k parity bits are lengthened or shortened in time so that the total duration of the n-k parity bits plus the synchronisation sequence is equal to the duration of the k information bits. This is so that in the receiver the information symbols may be output without interruption even if synchronisation is temporarily lost or if the error correction decoder is overloaded due to adverse propagation conditions. As shown in FIG. 11, the n-k parity bits plus the synchronisation sequence is frequency division multiplexed together with the k information bits, and the resulting signal modulated and transmitted. The receiver arrangement for the encoded WiFi bit stream in this embodiment of the invention is shown in FIG. 12. The received signal from the antenna is demodulated and the information bits are demultiplexed into a separate bit stream from the synchronisation sequences and parity bit streams. The idea is that the information bits have a direct output path so that under adverse propagation conditions where synchronisation may be lost, or the error correction system may be overloaded, the information bits, albeit with errors, continue to be output thereby producing a robust system. The output may be to a digital processor of the WiFi information or a conventional WiFi encoder or modulator to effect an increase in range of the WiFi signal by subsequently being received as a WiFi signal.

As shown in FIG. 12, with each sequence of k information bits and n-k parity bits, the synchronisation sequence is acquired which provides synchronisation information regarding the beginning of each codeword. Each codeword is decoded and a codeword is found from the (n,k) error correcting code which is the closest to the received information bits and parity bits in terms of Euclidean distance [3]. The information bits from the received information bit stream that differ from the codeword information bits are in error. The correct information bits are substituted for the incorrect information bits as shown in FIG. 12. In the event that propagation conditions are so poor that error correction becomes unreliable the procedure of substituting errored information bits with information bits from the error correcting decoder may be suspended. Poor propagation conditions may detected by observing a reduced margin in synchronisation detection.

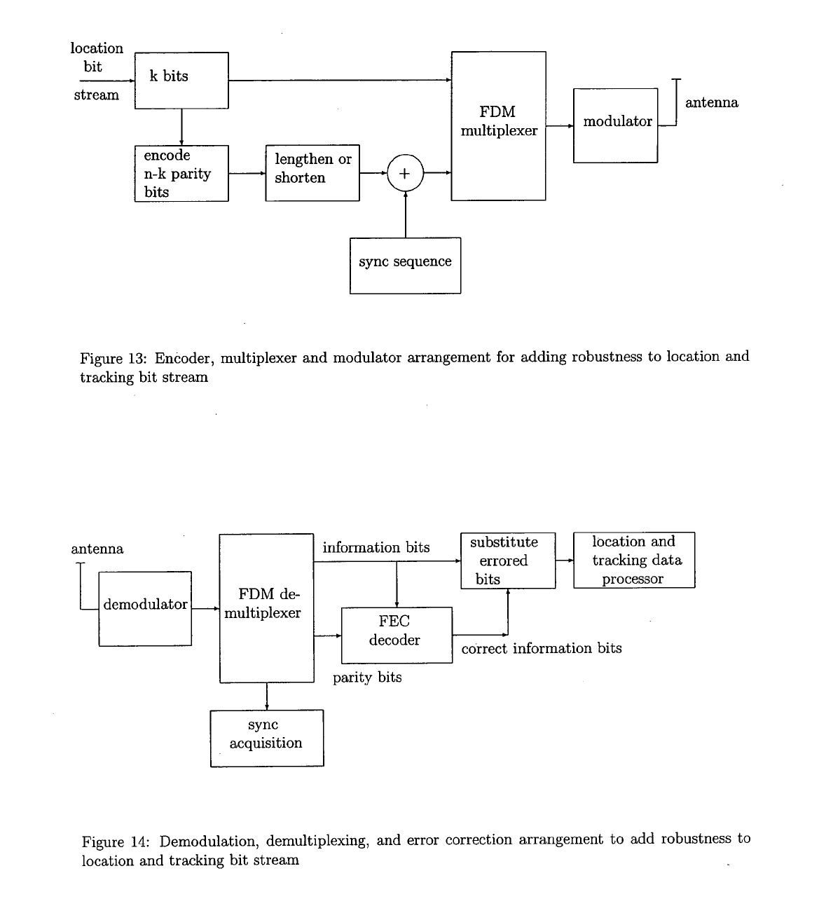

For the application of adding robustness to a location and tracking system in this embodiment of the invention, the transmitter arrangement is shown in FIG. 13. A conventional location and tracking system is envisaged in which each user or object to be tracked transmits periodically a unique bit stream which is used to locate and to track the user or object. At the transmitter of the user or object the unique bit stream is input k bits at a time as shown in FIG. 13. Each sequence of k bits is encoded into n-k parity bits to form a codeword from an error correcting code of total length n bits consisting of a total sequence of n bits made up of k information bits and n-k parity bits. As shown in FIG. 11 a synchronisation sequence is appended to every sequence of the n-k parity bits. The n-k parity bits are lengthened or shortened in time so that the total duration of the n-k parity bits plus the synchronisation sequence is equal to the duration of the k information bits. This is so that in the receiver the information symbols may be output without interruption even if synchronisation is temporarily lost or if the error correction decoder is overloaded due to adverse propagation conditions. As shown in FIG. 13, the n-k parity bits plus the synchronisation sequence is frequency division multiplexed together with the k information bits, and the resulting signal modulated and transmitted.

The receiver arrangement for the location and tracking system is shown in FIG. 14. The received signal from the antenna is demodulated and the information bits are demultiplexed into a separate bit stream from the synchronisation sequences and parity bit streams. As in the other applications for this embodiment of the invention the idea is that the information bits have a direct output path so that under adverse propagation conditions where synchronisation may be lost, or the error correction system may be overloaded, the information bits, possibly with errors, continue to be output thereby producing a robust system. The output is fed to the tracking and location processing system as shown in FIG. 14.

As shown in FIG. 14, with each sequence of k information bits and n-k parity bits, the synchronisation sequence is acquired which provides synchronisation information regarding the beginning of each codeword. Each codeword is decoded and a codeword is found from the (n,k) error correcting code which is the closest to the received information bits and parity bits in terms of Euclidean distance [3]. The information bits from the received information bit stream that differ from the codeword information bits are in error. The correct information bits are substituted for the incorrect information bits as shown in FIG. 12. In the event that propagation conditions are so poor that error correction becomes unreliable the procedure of substituting errored information bits with information bits from the error correcting decoder may be suspended. Poor propagation conditions may detected by observing a reduced margin in synchronisation detection.

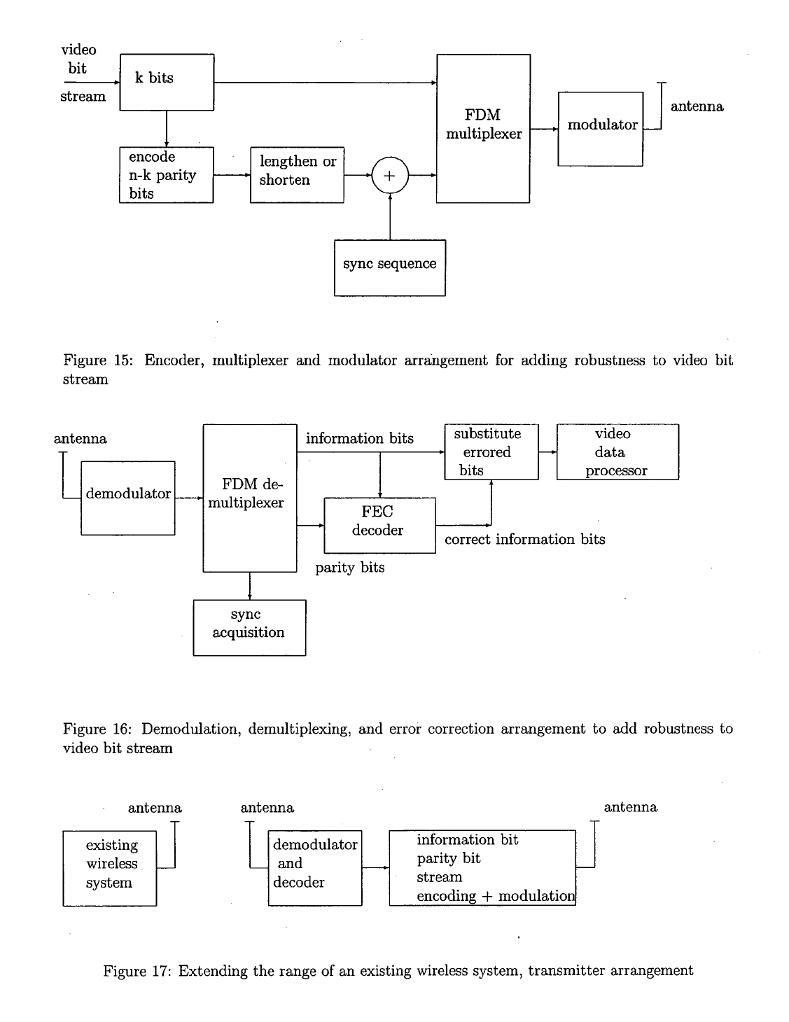

For the application of providing a robust video streaming system in this embodiment of the invention, the transmitter arrangement is shown in FIG. 15. A video stream including audio is envisaged to be encoded into a composite bit stream. At the transmitter the video bit stream is input k bits at a time as shown in FIG. 15. Each sequence of k bits is encoded into n-k parity bits to form a codeword from an error correcting code of total length n bits consisting of a total sequence of n bits made up of k information bits and n-k parity bits. As shown in FIG. 11 a synchronisation sequence is appended to every sequence of the n-k parity bits. The n-k parity bits are lengthened or shortened in time so that the total duration of the n-k parity bits plus the synchronisation sequence is equal to the duration of the k information bits. This is so that in the receiver the information symbols may be output without interruption even if synchronisation is temporarily lost or if the error correction decoder is overloaded due to adverse propagation conditions. As shown in FIG. 13, the n-k parity bits plus the synchronisation sequence is frequency division multiplexed together with the k information bits, and the resulting signal modulated and transmitted.

The receiver arrangement for the robust video streaming system is shown in FIG. 16. The received signal from the antenna is demodulated and the information bits are demultiplexed into a separate bit stream from the synchronisation sequences and parity bit streams. As in the other applications for this embodiment of the invention the idea is that the information bits have a direct output path so that under adverse propagation conditions where synchronisation may be lost, or the error correction system may be overloaded, the information bits, possibly with errors, continue to be output thereby producing a robust system. The corrected binary information stream output is fed to the video data processor as shown in FIG. 16.

As shown in FIG. 16, with each sequence of k information bits and n-k parity bits, the synchronisation sequence is acquired which provides synchronisation information regarding the be-ginning of each codeword. Each codeword is decoded and a codeword is found from the (n, k) error correcting code which is the closest to the received information bits and parity bits in terms of Euclidean distance [3]. The information bits from the received information bit stream that differ from the codeword information bits are in error. The correct information bits are substituted for the incorrect information bits as shown in FIG. 16. In the event that propagation conditions are so poor that error correction becomes unreliable the procedure of substituting errored information bits with information bits from the error correcting decoder may be suspended. Poor propagation conditions may detected by observing a reduced margin in synchronisation detection.

For the application of range extension of an existing wireless system such as a WiFi or Bluetooth system in this embodiment of the invention, the signal from an existing wireless system is received, demodulated and decoded in the overall arrangement for the transmitter as shown in FIG. 17. After conventional demodulation and decoding the bit stream is input k bits at a time as shown in FIG. 11. Each sequence of k bits is encoded into n-k parity bits to form a codeword from an error correcting code of total length n bits consisting of a total sequence of n bits made up of k information bits and n-k parity bits. As shown in FIG. 11 a synchronisation sequence is appended to every sequence of the n-k parity bits. The n-k parity bits are lengthened or shortened in time so that the total duration of the n-k parity bits plus the synchronisation sequence is equal to the duration of the k information bits. This is so that in the receiver the information symbols may be output without interruption even if synchronisation is temporarily lost or if the error correction decoder is overloaded due to adverse propagation conditions. As shown in FIG. 11, the n-k parity bits plus the synchronisation sequence is frequency division multiplexed together with the k information bits, and the resulting signal is modulated and transmitted as shown in FIG. 17.

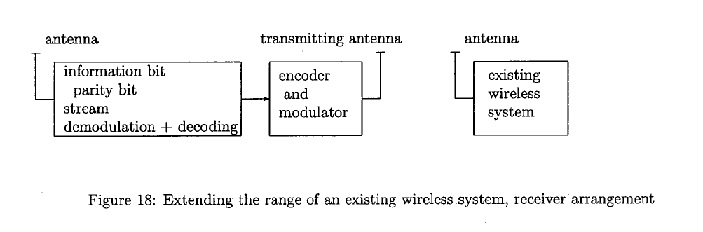

The overall receiver arrangement is shown in FIG. 18. The received signal from the antenna is demodulated and the information bits are demultiplexed into a separate bit stream from the synchronisation sequences and parity bit streams. The information bits have a direct output path so that under adverse propagation conditions where synchronisation may be lost, or the error correction system may be overloaded, the information bits, albeit with errors, continue to be output thereby producing a robust system. The corrected bit stream output is encoded and modulated in accordance with the format of the existing wireless system so that a compatible wireless signal is produced at the transmitting antenna shown in FIG. 18. The compatible radiated signal is received in the normal manner by the existing wireless system as shown in FIG. 18.

It is apparent that the various parameters of the invention that provide robustness to the wireless link may be varied in a time varying manner using the return channel of the communications link. The bandwidth of the baseband signals may be reduced, the number of baseband channels may be reduced or more parity symbols may be transmitted in order to increase the robustness of the wireless link in response to adverse propagation conditions. In this manner an adaptive system may be realised that responds to propagation conditions of the wireless link.

### REFERENCES

[1] J. G. Proakis, Digital Communications, McGraw-Hill, 1997
[2] C. Wooton, A Practical Guide to Video and Audio Compression, Elsevier, 2005
[3] S. Lin and D. J. Costello, Jr., Error Control Coding, 2^{nd} ed., Pearson Prentice Hall, 2004
[4] L. W. Couch, Digital and Analog Communication Systems, 5^{th} ed., Prentice Hall, 1997
[5] R. J. Sutton, Secure Communications: Applications and Management, John Wiley and Sons Ltd, 2001
[6] H. J. Beker, Analogue Speech Security Systems, Springer Berlin/Heidelberg, 1995
[7] M. Tomlinson, C. J. Tjhai, M. A. Ambroze, and M. Z. Ahmed, Error Correction System using the Discrete Fourier Transform, U.S. patent application Ser. No. 12/057,781, 2008

1. An information transfer system comprising:
a transmitter; and
a receiver,
wherein data received and/or stored locally by the transmitter is selected by a user using a remote control channel and decoded by the transmitter into baseband components which are filtered according to user preferences communicated to the transmitter by the remote control channel, and each of these baseband components are encoded by the transmitter using an error correcting code into an information sample stream and a second stream consisting of sequences of parity symbols plus synchronisation sequences, and each stream is frequency division and/or time division multiplexed by the transmitter into a single signal which is scrambled by the transmitter so as to produce a signal power spectral density which has a low peak to average ratio and the scrambled signal stream is digitally modulated by the transmitter onto a carrier which in turn is radiated by an antenna as a wireless signal,
wherein the wireless signal is received by the receiver using a second antenna and demodulated into a single signal stream which is descrambled and then demultiplexed into baseband information streams together with associated parity symbols and synchronisation sequences and in which the synchronisation information is used to decode each received codeword generating a sequence of information symbols which are substituted for information samples received in error and the resulting information streams are filtered according to user preferences and output.

2. The system according to claim 1, wherein the data received at the transmitter comprise a radio channel streamed over the internet.

3. The system according to claim 1, wherein the data received at the transmitter comprise talking books or recorded music streamed over the internet.

4. A system for extending a communication range of a wireless data communications link, comprising:
a transmitter; and
a receiver,
wherein the transmitter is adapted to encode a bit stream in each direction over the link using an error correcting code to produce an information bit stream and a second bit stream consisting of sequences of parity bits plus synchronisation sequences,
wherein the transmitter is further adapted to frequency division multiplex and/or time division multiplex each stream into a single signal and scramble it so as to produce a signal power spectral density which has a low peak to average ratio,
wherein the scrambled signal stream is modulated onto a carrier which in turn is radiated by an antenna as a wireless signal; and
wherein the receiver is adapted to receive the wireless signal via a second antenna and demodulate it into a single signal stream which is descrambled and then demultiplexed into a baseband information bit stream together with an associated baseband parity bit stream and synchronisation sequences,
wherein the receiver is further adapted to use the synchronisation information to decode each received codeword thereby generating a sequence of information bits which are substituted for information bits received in error.

5. The system according to claim 4, wherein the wireless data communications link is a WiFi network and wherein the resulting information bit stream is processed by a WiFi device.

6. A system for extending a communication range of a first wireless data communications link using a second wireless data communications link, comprising:
a transmitter; and
a receiver,
wherein the transmitter is adapted to receive and to decode the data being sent over the first wireless link and to encode the resulting bit stream in each direction of transmission over the link using an error correcting code to produce an information bit stream and a second bit stream consisting of sequences of parity bits plus synchronisation sequences,
wherein the transmitter is further adapted to frequency division and/or time division multiplex each stream into a single signal and scramble it so as to produce a signal power spectral density which has a low peak to average ratio,
wherein the scrambled signal stream is modulated onto a carrier which in turn is radiated by an antenna as a wireless signal; and
wherein the receiver is adapted to receive the wireless signal via a second antenna and demodulate it into a single signal stream which is descrambled and then demultiplexed into a baseband information bit stream together with an associated baseband parity bit stream and synchronisation sequences,
wherein the receiver is further adapted to use the synchronisation information to decode each received codeword thereby generating a sequence of information bits which are substituted for information bits received in error and these bits are encoded and modulated onto a wireless carrier compatible with the receiver of the first wireless link.

7. The system according to claim 4, wherein the robustness of a tracking and location system is increased by encoding the unique bit stream which originates from each user or object to be tracked using the error correcting code to produce the information bit stream and the second bit stream.

8. The system according to claim 6, wherein the first wireless data communications link and/or second wireless data communications link is a WiFi network and wherein the resulting information bit stream is processed by a WiFi device.

9. The system according to claim 6, wherein the first wireless data communications link and/or second wireless data communications link is a Bluetooth link and wherein the resulting information bit stream is processed by a Bluetooth device.

10. The system according to claim 4, wherein the robustness of a video streaming system is increased by encoding the video bit stream using the error correcting code to produce the information bit stream and the second bit stream.

11. The system according to claim 6, wherein the robustness of a tracking and location system is increased by encoding the unique bit stream which originates from each user or object to be tracked using the error correcting code to produce the information bit stream and the second bit stream.

10. The system according to claim 6, wherein the robustness of a video streaming system is increased by encoding the video bit stream using the error correcting code to produce the information bit stream and the second bit stream.
